(19) United States
(12) Patent Application Publication
(10) Pub. No.: US 2008/0251875 A1
(43) Pub. Date: Oct. 16, 2008

(54) SEMICONDUCTOR PACKAGE

(75) Inventors: YING-CHENG WU, Tu-Cheng (TW); KUN-HSIAO LIU, Tu-Cheng (TW)

Correspondence Address: PCE INDUSTRY, INC.;ATT. CHENG-JU CHIANG, 458 E. LAMBERT ROAD, FULLERTON, CA, 92835, US

(73) Assignee: HON HAI PRECISION INDUSTRY CO., LTD., Tu-Cheng (TW)

(21) Appl. No.: 11/850,619

(22) Filed: Sep. 5, 2007

(30) Foreign Application Priority Data
Apr. 13, 2007 (CN) 200710200457.7

(51) Int. Cl. H01L 23/22; H01L 31/0203

(52) U.S. Cl. 257/434; 257/433; 257/698; 257/E23.194; 257/E23.128; 257/E31.117

(57) ABSTRACT

An exemplary semiconductor package includes a substrate, at least one passive component, an insulative layer and a chip. The substrate defines a cavity therein. The at least one passive component is disposed within the cavity, and is electrically connected to the substrate. The insulative layer is received in the cavity, and encases the at least one passive component. The chip is disposed on the insulative layer, and is electrically connected to the substrate. The semiconductor package packaging the at least one passive component within the cavity and under the chip can improve a space usage thereof, thus a packaging scale of the semiconductor package could be reduced.

### BACKGROUND

1. Technical Field

The present invention relates to semiconductor packaging technology and, particularly, relates to a minimized semiconductor package.

2. Description of Related Art

Referring to FIG. 3, a semiconductor package 100a typically includes a chip 11a, a plurality of passive components 12a, and a substrate 13a. The chip 11a and the passive components 12a are disposed on the substrate 13a, and are electrically coupled to the substrate 13a. Normally, the chip 11a is placed on a central portion of a surface 131a of the substrate 13a, and the passive components 12a are placed around the chip 11a. Obviously, the semiconductor package 100a thus packaged tends to be bulky, since the substrate 13a should be formed with the surface 131a large enough to receive both the chip 11a and the passive components 12a. Additionally, the passive components 12a surrounding the chip 11a may limit a space for bonding wires from the chip 11a to the substrate 13a.

Therefore, it is desirable to provide a semiconductor package, which can overcome the above-mentioned problems.

### SUMMARY

In the present embodiment, a semiconductor package includes a substrate, at least one passive component, an insulative layer and a chip. The substrate defines a cavity therein. The at least one passive component is placed within the cavity, and is electrically connected to the substrate. The insulative layer is received in the cavity, and encases the at least one passive component. The chip is disposed on the insulative layer, and is electrically connected to the substrate.

### BRIEF DESCRIPTION OF THE DRAWINGS

Many aspects of the present semiconductor package should be better understood with reference to the following drawings. The components in the drawings are not necessarily drawn to scale, the emphasis instead being placed upon clearly illustrating the principles of the present semiconductor package. Moreover, in the drawings, like reference numerals designate corresponding parts throughout the several views.

FIG. 1 is schematic, cross-sectional view of a semiconductor package, according to a first preferred embodiment;

FIG. 2 is a schematic, cross-sectional view of a semiconductor package, according to a second preferred embodiment; and

FIG. 3 is a top view of a semiconductor package, according to related art.

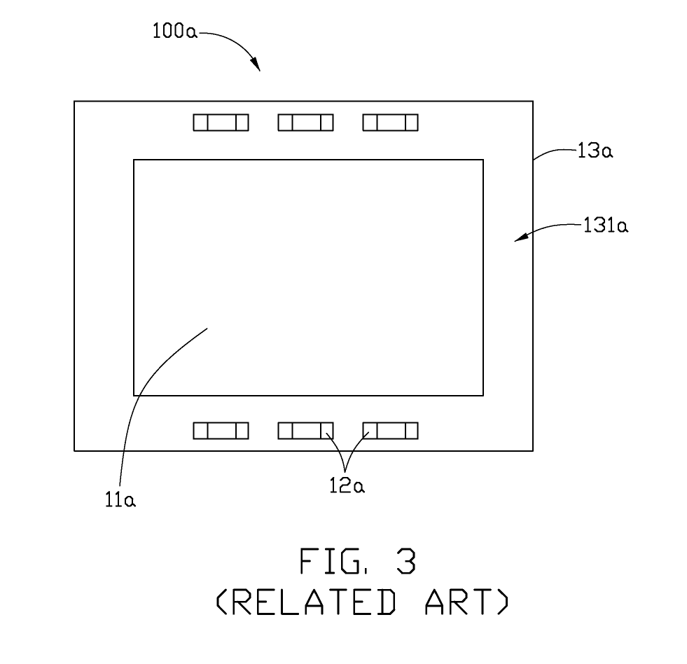

### DETAILED DESCRIPTION OF THE EMBODIMENTS

Embodiments of the present semiconductor package will be described below in detail with reference to the drawings.

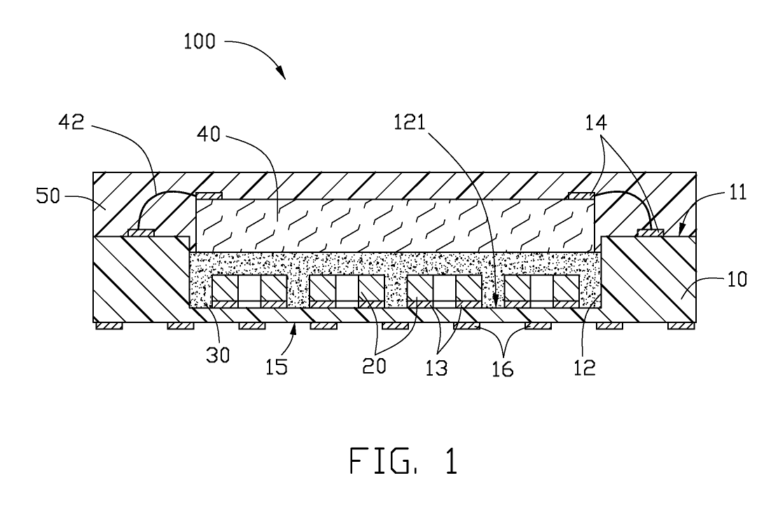

Referring to FIG. 1, a semiconductor package 100, according to a first embodiment, includes a substrate 10, at least one passive component 20, an insulative layer 30, a chip 40, and a capsule 50. The substrate 10 defines a cavity 12 therein. The at least one passive component 20 is placed within the cavity 12, and is electrically connected to the substrate 10. The insulative layer 30 is received in the cavity 12, and encases the at least one passive component 20. The chip 40 is disposed on the insulative layer 30, and is electrically connected to the substrate 10. The capsule 50 is disposed on the substrate 10 for securely encasing the chip 40.

The substrate 10 could be, typically, a circuit-bearing substrate including a packaging surface 11 (e.g., upper surface), the cavity 12 is defined in the packaging surface 11. Additionally, the substrate 10 further includes a plurality of first welding pads 13 formed on a bottom surface 121 of the cavity 12 and a plurality of second welding pads 14 formed on the packaging surface 11. The first welding pads 13 and the second welding pads 14 are respectively configured for electrically coupling the at least one passive component 20 and the substrate 10, the chip 40 and the substrate 10. Specifically, the substrate 10 further includes a plurality of third welding pads 16 formed on a bottom surface 15 (i.e., surface opposite to the packaging surface 11) of the substrate 10. The third welding pads 16 are configured for coupling the semiconductor package 100 and an outside circuit (not shown). The third welding pads 16 can be patterned in form of: e.g., BGA (ball gird array), LCC (leadless chip carrier) or leadframe.

The substrate 10 can be made of material such as plastic, ceramic or glass. In this illustrated embodiment, the substrate 10 is, advantageously, made of plastic comprised of epoxy resin doped with organic silicon. Also, other alternative type plastic, e.g., plastic comprised of epoxy resin doped with glass fiber or plastic comprised of epoxy doped with aramid may be considered, within the scope of the present semiconductor package.

The cavity 12 is, beneficially, defined on a central portion of the packaging surface 11. Opportunely, a width and a length of the cavity 12 are respectively larger than that of the chip 40, and the depth of the cavity 12 is higher than a height of the insulative layer 30. Thus, the chip 40 can be partially/totally received in the cavity 12 to reduce a height of the semiconductor package 100. In this illustrated embodiment, the chip 40 is partially received in the cavity 12.

The at least one passive component 20 may be at least one SMD (surface mounted device), and can be mounted on the first welding pads using SMT (surface mounted technology). Specifically, the at least one passive component 20 can be a resistor or capacitor. In this illustrate embodiment, the at least one passive component 20 includes a plurality of capacitors (e.g., decoupling capacitor) for reduce an electric noise generated between an electric power source and an electric ground.

The insulative layer 30 could be made of curable adhesive such as UV (ultraviolet) curable adhesive, the chip 40 is directly attached to the insulative layer 30. Specifically, the insulative layer 30 is, advantageously, formed by the steps of: (1) filling the curable adhesive in liquid state into the cavity till the curable adhesive cover the at least one passive component 20; (2) curing the curable adhesive to a solid-liquid state; (3) placing the chip 40 on the curable adhesive; and (4) curing the curable adhesive completely. Thus, the insulative layer 30 is formed with an encapsulating function for the at least one passive component and a supporting function for the chip 40.

The chip 40 is coupled to the second welding pads 14 using a plurality of wires 42. The wires 42 are, advantageously, made of an excellent conductor, such as gold, silver or copper.

The capsule 50 is disposed on the packaging surface 11, and is, advantageously, sized so as to cover the packaging surface 11. Thus, the capsule 50 can also encase the second welding pads 14 and the wires 42. The capsule 50 can be made of plastic or ceramic. In this embodiment, the capsule 50 is made of plastic, and formed by any of various techniques, such as transfer molding or injection molding.

The semiconductor package 100 packaging the at least one passive component 20 within the cavity and under the chip 40 can improve a space usage thereof, thus a packaging scale of the semiconductor package 100 could be reduced.

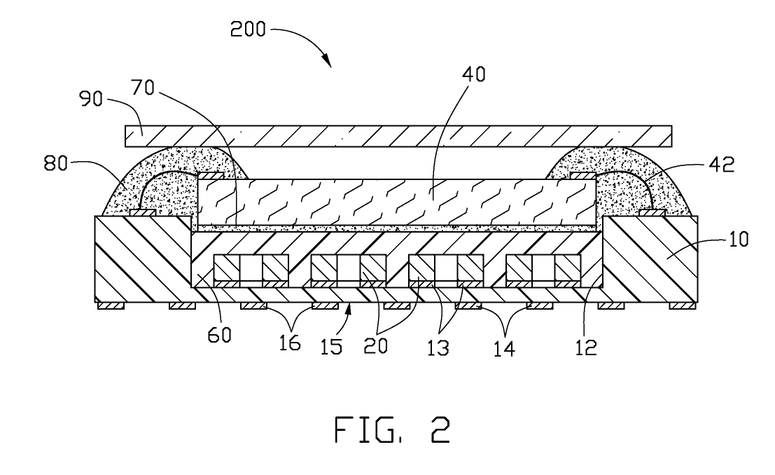

Referring to FIG. 2, another semiconductor package 200, according to a second embodiment, is essentially similar to the semiconductor package 100 except with respect to the insulative layer and the capsule.

In the second illustrated embodiment, the insulative layer 60 is, beneficially, made of plastic, the chip 40 is attached to the insulative layer 60 via an adhesive layer 70. Specifically, the insulative layer 60 can be formed by various techniques, such as transfer molding or injection molding. The adhesive is, usefully, formed by curable adhesive.

The chip 40 is configured for imaging, accordingly, the semiconductor package 200 further comprises a curable adhesive 80 and a transparent cover 90 instead of the capsule 50. The curable adhesive 80 encapsulates the second welding pads 14 and the wires 42, and the transparent cover 90 is attached to the curable adhesive 80 to encase the chip 40.

It will be understood that the above particular embodiments and methods are shown and described by way of illustration only. The principles and the features of the present invention may be employed in various and numerous embodiment thereof without departing from the scope of the invention as claimed. The above-described embodiments illustrate the scope of the invention but do not restrict the scope of the invention.

What is claimed is:

1. A semiconductor package comprising:
a substrate defining a cavity therein;
at least one passive component disposed within the cavity and electrically connected to the substrate;
an insulative layer received in the cavity, the insulative layer encasing the at least one passive component; and
a chip disposed on the insulative layer and electrically connected to the substrate.

2. The semiconductor package as claimed in the claim 1, wherein a width and a length of the cavity are respectively larger than that of the chip.

3. The semiconductor package as claimed in the claim 2, wherein the depth of the cavity is higher than a height of the insulative layer.

4. The semiconductor package as claimed in the claim 3, wherein the chip is partially received in the cavity.

5. The semiconductor package as claimed in the claim 3, wherein the chip is completely received within the cavity.

6. The semiconductor package as claimed in the claim 1, wherein the insulative layer is made of curable adhesive, the chip being directly attached to the insulative layer.

7. The semiconductor package as claimed in the claim 1, wherein the insulative layer is made of plastic; the chip being attached to the insulative layer via an adhesive layer.

8. The semiconductor package as claimed in the claim 6, wherein the insulative layer is formed using a technique selected from a group consisting of transfer molding and injection molding.

9. The semiconductor package as claimed in the claim 1, wherein the substrate further comprises a plurality of welding pads formed on a bottom surface of the cavity, the welding pads being configured for electrically coupling the at least one passive component and the substrate.

10. The semiconductor package as claimed in the claim 1, wherein the substrate includes a packaging surface, the cavity being defined in the packaging surface.

11. The semiconductor package as claimed in the claim 10, wherein the substrate further includes a plurality of welding pads formed on the packaging surface, the welding pads being configured for electrically coupling the chip and the substrate.

12. The semiconductor package as claimed in the claim 10, wherein the substrate further comprises a plurality of welding pads formed on a surface of the substrate, the surface of the substrate being opposite to the packaging surface.

13. The semiconductor package as claimed in the claim 12, wherein the welding pads are patterned in the form selected from a group of: ball grid array, leadless chip carrier and leadframe.

14. The semiconductor package as claimed in the claim 1, further comprising a capsule disposed on the substrate for securely encasing the chip.

15. The semiconductor package as claimed in the claim 14, wherein the capsule is made of material selected from a group consisting of plastics and ceramics by technique selected from a group of transfer molding and injection molding.

16. The semiconductor package as claimed in the claim 1, wherein the chip is an imaging chip, the semiconductor package further comprising a transparent cover encasing the chip via a curable adhesive.

17. The semiconductor package as claimed in the claim 1, wherein the substrate is made of material selected from a group consisting of plastic, ceramic and glass.

18. The semiconductor package as claimed in the claim 1, wherein the substrate is made from compound selected from a group consisting of epoxy resin doped with organic silicon, epoxy resin doped with glass fiber, and epoxy resin doped with aramid.

19. A semiconductor package comprising:
a substrate defining a cavity therein;
at least one passive component disposed in the cavity and electrically connected to the substrate;
an insulative layer filled in the cavity to encase the at least one passive component;
a chip electrically connected to the substrate and disposed on the insulative layer in such a manner that the chip is overlapped with the at least one passive component in a direction perpendicular to a join surface between the chip and the insulative layer; and
a capsule attached to the substrate for encasing the chip.

20. The semiconductor package as claimed in the claim 19, wherein the chip is an imaging chip and the at least one passive component is at least one resistor or capacitor.
